(19) United States
(12) Patent Application Publication
(10) Pub. No.: US 2010/0282306 A1
(43) Pub. Date: Nov. 11, 2010

(54) Multijunction Solar Cells with Group IV/III-V Hybrid Alloys

(75) Inventors: Paul Sharps, Albuquerque, NM (US); Fred Newman, Albuquerque, NM (US)

Correspondence Address: EMCORE CORPORATION, 1600 EUBANK BLVD, S.E., ALBUQUERQUE, NM, 87123, US

(73) Assignee: Emcore Solar Power, Inc., Albuquerque, NM (US)

(21) Appl. No.: 12/463,216

(22) Filed: May 8, 2009

(51) Int. Cl. H01L 31/0336; H01L 31/18

(52) U.S. Cl. 136/255; 438/94; 257/E31.005; 257/E21.09

(57) ABSTRACT

A method of manufacturing a solar cell by providing a germanium semiconductor growth substrate; and depositing on the semiconductor growth substrate a sequence of layers of semiconductor material forming a solar cell, including a subcell composed of a group IV/III-V hybrid alloy.

### REFERENCE TO RELATED APPLICATIONS

This application is related to co-pending U.S. patent application Ser. No.______ and Ser. No. ______, filed ______, 2009.

### BACKGROUND OF THE INVENTION

1. Field of the Invention

The present invention relates to the field of semiconductor devices, and to fabrication processes and devices such as multijunction solar cells based on Group IV/III-V hybrid semiconductor compounds.

3. Description of the Related Art

Solar power from photovoltaic cells, also called solar cells, has been predominantly provided by silicon semiconductor technology. In the past several years, however, high-volume manufacturing of III-V compound semiconductor multijunction solar cells for space applications has accelerated the development of such technology not only for use in space but also for terrestrial solar power applications. Compared to silicon, III-V compound semiconductor multijunction devices have greater energy conversion efficiencies and generally more radiation resistance, although they tend to be more complex to manufacture. Typical commercial III-V compound semiconductor multijunction solar cells have energy efficiencies that exceed 27% under one sun, air mass 0 (AM0), illumination, whereas even the most efficient silicon technologies generally reach only about 18% efficiency under comparable conditions. Under high solar concentration (e.g., 500×), commercially available III-V compound semiconductor multijunction solar cells in terrestrial applications (at AM1.5D) have energy efficiencies that exceed 37%. The higher conversion efficiency of III-V compound semiconductor solar cells compared to silicon solar cells is in part based on the ability to achieve spectral splitting of the incident radiation through the use of a plurality of photovoltaic regions with different band gap energies, and accumulating the current from each of the regions.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as payloads become more sophisticated, the power-to-weight ratio of a solar cell becomes increasingly more important, and there is increasing interest in lighter weight, “thin film” type solar cells having both high efficiency and low mass.

Typical III-V compound semiconductor solar cells are fabricated on a semiconductor wafer in vertical, multijunction structures. The individual solar cells or wafers are then disposed in horizontal arrays, with the individual solar cells connected together in an electrical series circuit. The shape and structure of an array, as well as the number of cells it contains, are determined in part by the desired output voltage and current.

### SUMMARY OF THE INVENTION

Briefly, and in general terms, an aspect of the present invention comprises a method of manufacturing a solar cell comprising: providing a germanium semiconductor growth substrate; depositing on said semiconductor growth substrate a sequence of layers of semiconductor material forming a solar cell, including a subcell composed of a group IV/III-V hybrid alloy.

In another aspect, the present invention comprises a method of manufacturing a solar cell by providing a semiconductor growth substrate; and depositing on said semiconductor growth substrate a sequence of layers of semiconductor material forming a solar cell, including at least one layer composed of GeSiSn and one layer grown over the GeSiSn layer composed of Ge.

In another aspect, a solar cell according to an aspect of the present invention comprises a first solar subcell composed of GeSiSn and having a first band gap; a second solar subcell composed of GaAs, InGaAsP, or InGaP and disposed over the first solar subcell having a second band gap greater than the first band gap and lattice matched to said first solar subcell; and a third solar subcell composed of GaInP and disposed over the second solar subcell having a third band gap greater than the second band gap and lattice matched with respect to the second subcell.

Some implementations of the present invention may incorporate or implement fewer of the aspects and features noted in the foregoing summaries.

Additional aspects, advantages, and novel features of the present invention will become apparent to those skilled in the art from this disclosure, including the following detailed description as well as by practice of the invention. While the invention is described below with reference to preferred embodiments, it should be understood that the invention is not limited thereto. Those of ordinary skill in the art having access to the teachings herein will recognize additional applications, modifications and embodiments in other fields, which are within the scope of the invention as disclosed and claimed herein and with respect to which the invention could be of utility.

### BRIEF DESCRIPTION OF THE DRAWINGS

The invention will be better and more fully appreciated by reference to the following detailed description when considered in conjunction with the accompanying drawings, wherein:

FIG. 1 is a graph representing the bandgap of certain binary materials and their lattice constants;

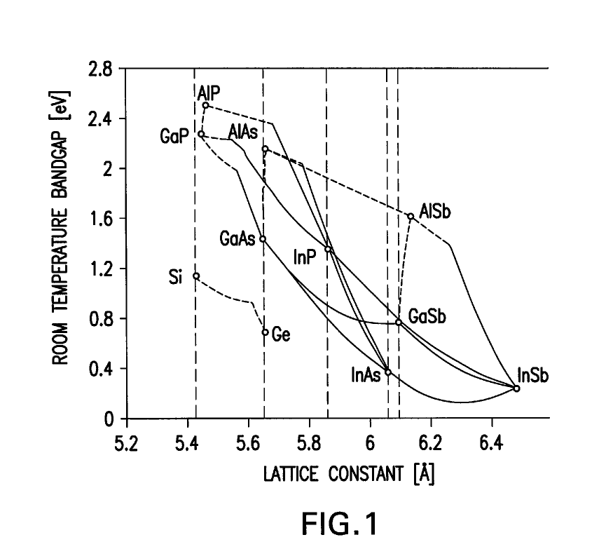

FIG. 2A is a cross-sectional view of the solar cell of the invention after the deposition of semiconductor layers on the growth substrate according to one embodiment of the present invention;

FIG. 2B is a cross-sectional view of the solar cell of the invention after the deposition of semiconductor layers on the growth substrate according to another embodiment of the present invention;

FIG. 2C is a cross-sectional view of the solar cell of the invention after the deposition of semiconductor layers on the growth substrate according to another embodiment of the present invention;

FIG. 3 is a highly simplified cross-sectional view of the solar cell of either FIG. 2A, 2B or 2C after the next process step;

FIG. 4 is a cross-sectional view of the solar cell of FIG. 3 after the next process step;

FIG. 5 is a cross-sectional view of the solar cell of FIG. 4 after the next process step;

FIG. 6A is a top plan view of a wafer in which four solar cells are fabricated;

FIG. 6B is a bottom plan view of the wafer of FIG. 6A;

FIG. 6C is a top plan view of a wafer in which two solar cells are fabricated;

FIG. 7 is a cross-sectional view of the solar cell of FIG. 5 after the next process step;

FIG. 8 is a cross-sectional view of the solar cell of FIG. 7 after the next process step in which a cover glass is attached; and

FIG. 9 is a graph of the doping profile in the base and emitter layers of a subcell in the solar cell according to the present invention.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale. The basic concept of fabricating a multijunction solar cell is to grow the subcells of the solar cell on a substrate in an ordered sequence. That is, the low band gap subcells (i.e. subcells with band gaps in the range of 0.7 to 1.2 eV), are grown epitaxially directly on a semiconductor growth substrate, such as for example GaAs or Ge, and such subcells are consequently lattice matched to such substrate. One or more intermediate band gap middle subcells (i.e. with band gaps in the range of 1.0 to 2.4 eV) can then be grown on the low band gap subcell.

A top or upper subcell is formed over the middle subcell such that the top subcell is substantially lattice matched with respect to the middle subcell and such that the top subcell has a third higher band gap (i.e., a band gap in the range of 1.6 to 2.4 eV).

A variety of different features and aspects of multijunction solar cells are disclosed in the related applications noted above. Some or all of such features may be included in the structures and processes associated with the solar cells of the present invention.

The lattice constants and electrical properties of the layers in the semiconductor structure are preferably controlled by specification of appropriate reactor growth temperatures and times, and by use of appropriate chemical composition and dopants. The use of a vapor deposition method, such as Organo Metallic Vapor Phase Epitaxy (OMVPE), Metal Organic Chemical Vapor Deposition (MOCVD), or other vapor deposition methods, or other deposition techniques such as Molecular Beam Epitaxy (MBE), for the reverse growth may enable the layers in the monolithic semiconductor structure forming the cell to be grown with the required thickness, elemental composition, dopant concentration and grading and conductivity type.

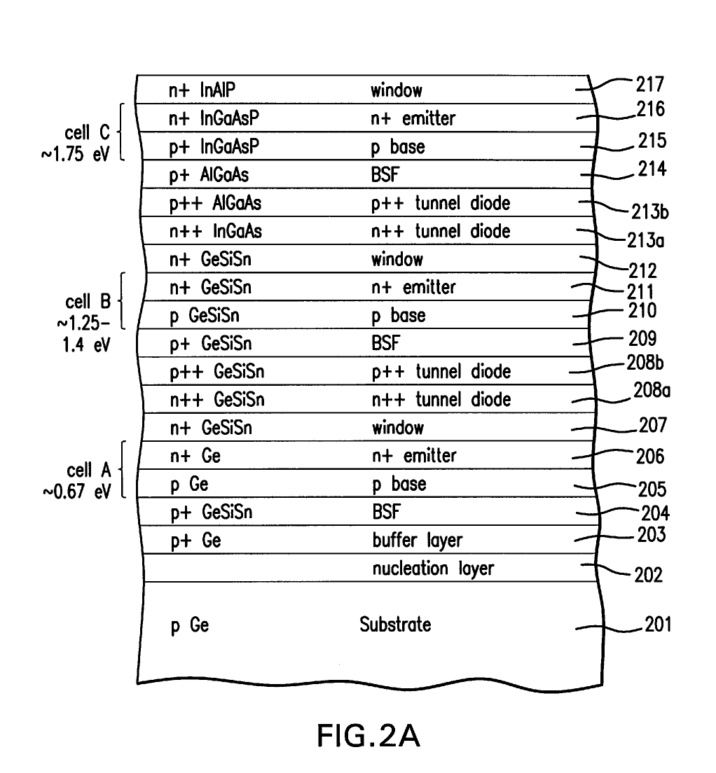

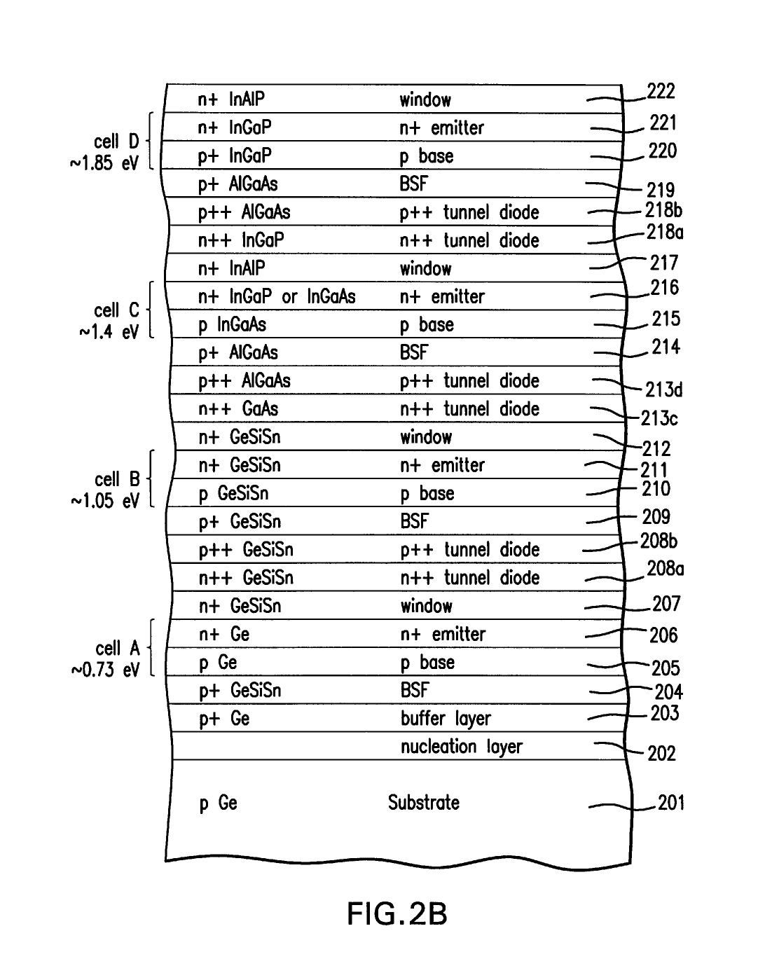

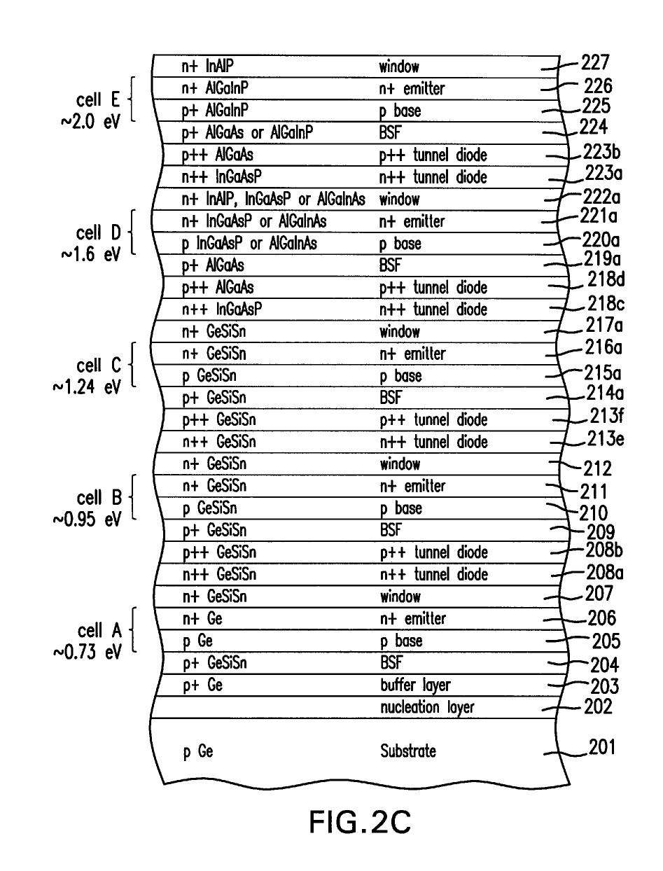

FIG. 2A depicts the multijunction solar cell according to the present invention after the sequential formation of the three subcells A, B and C on a germanium growth substrate. More particularly, there is shown a substrate 201, which is preferably germanium (Ge) or other suitable material.

In the case of a Ge substrate, a nucleation layer 202 may be deposited directly on the substrate 201. On the substrate 201, or over the nucleation layer 202 (in the case of a Ge substrate), a buffer layer 203 is further deposited. In the case of Ge substrate, the buffer layer 203 is preferably p+ type Ge. A BSF layer 204 of p+ type GeSiSn is then deposited on layer 203. The subcell A, consisting of a p type base layer 205 and a n+ type emitter layer 206 composed of germanium, is then epitaxially deposited on the BSF layer 204. The subcell A is generally latticed matched to the growth substrate 201. Subcell A may have a band gap of approximately 0.67 eV.

The BSF layer 204 drives minority carriers from the region near the base/BSF interface surface to minimize the effect of recombination loss. In other words, a BSF layer 204 reduces recombination loss at the backside of the solar subcell A and thereby reduces the recombination in the base.

It should be noted that the multijunction solar cell structure could be formed by any suitable combination of group III to V elements listed in the periodic table subject to lattice constant and bandgap requirements, wherein the group III includes boron (B), aluminum (A1), gallium (Ga), indium (In), and thallium (T). The group IV includes carbon (C), silicon (Si), germanium (Ge), and tin (Sn). The group V includes nitrogen (N), phosphorus (P), arsenic (As), antimony (Sb), and bismuth (Bi).

On top of the base layer 206 a window layer 207, preferably n+ type GeSiSn, is deposited, and used to reduce recombination loss.

On top of the window layer 207 is deposited a sequence of heavily doped p-type and n-type layers 208a and 208b that form a tunnel diode, i.e. an ohmic circuit element that connects subcell A to subcell B. Layer 208a is preferably composed of n++GaAs, and layer 208b is preferably composed of p++A1GaAs.

On top of the tunnel diode layers 208a/208b a BSF layer 209 is deposited, preferably p+ type InGaAs. More generally, the BSF layer 209 used in the subcell B operates to reduce the interface recombination loss. It should be apparent to one skilled in the art, that additional layer(s) may be added or deleted in the cell structure without departing from the scope of the present invention.

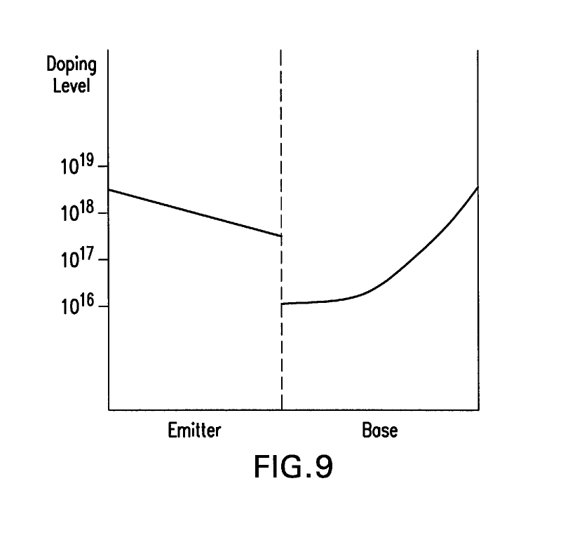

On top of the BSF layer 209, the layers of subcell B are deposited: the p type base layer 210 and the n+ type emitter layer 211. These layers are preferably composed of InGaAs, although any other suitable materials consistent with lattice constant and bandgap requirements may be used as well. Thus, subcell B may be composed of a GaAs, GaInP, GaInAs, GaAsSb, or GaInAsN emitter region and a GaAs, GaInAs, GaAsSb, or GaInAsN base region. The band gap of subcell B may be approximately 1.25 to 1.4 eV. The doping profile of layers 210 and 211 according to the present invention will be discussed in conjunction with FIG. 9.

On top of the subcell B is deposited a window layer 212 which performs the same function as the window layer 207. The p++/n++tunnel diode layers 213a and 213b respectively are deposited over the window layer 212, similar to the layers 208a and 208b, forming an ohmic circuit element to connect subcell B to subcell C. The layer 213a is preferably composed of n++GaInP, and layer 213b is preferably composed of p++A1GaAs.

A BSF layer 214, preferably composed of p+ type InGaA1P, is then deposited over the tunnel diode layer 213b. This BSF layer operates to reduce the recombination loss in subcell “C”. It should be apparent to one skilled in the art that additional layers may be added or deleted in the cell structure without departing from the scope of the present invention.

On top of the BSF layer 214 the layers of subcell C are deposited: the p type base layer 215 and the n+ type emitter layer 216. These layers are preferably composed of p type InGaAs or InGaP and n+ type InGaAs or InGaP, respectively, although any other suitable materials consistent with lattice constant and bandgap requirements may be used as well. The band gap of subcell C may be approximately 1.75 eV. The doping profile of layers 215 and 216 according to the present invention will be discussed in conjunction with FIG. 9.

A window layer 217, preferably composed of n+ type InA1P is then deposited on top of the subcell C, the window layer performing the same function as the window layers 207 and 212.

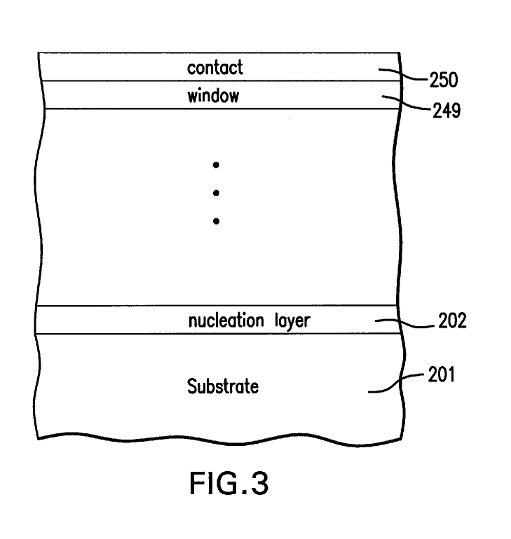

The description of subsequent processing steps in the fabrication of the solar cell in the embodiment of FIG. 2A will be described beginning with the description of FIG. 3 and subsequent Figures. Meanwhile, we will describe other embodiments of the multijunction solar cell semiconductor structure.

FIG. 2B depicts the multijunction solar cell in another embodiment according to the present invention after the sequential formation of the four subcells A, B, C, and D on a germanium growth substrate. More particularly, there is shown a substrate 201, which is preferably germanium (Ge) or other suitable material.

The composition of layers 202 through 212 in the embodiment of FIG. 2B are similar to those described in the embodiment of FIG. 2A, but with different elemental compositions or dopant concentrations necessary to achieve to different band gaps, and therefore the description of such layers need not be repeated here. In particular, in the embodiment of FIG. 2B, the band gap of subcell A may be approximately 0.73 eV, and the band gap of subcell B may be approximately 1.05 eV.

On top of the window layer 212 is deposited a sequence of heavily doped p-type and n-type layers 213c and 213d that form a tunnel diode, i.e. an ohmic circuit element that connects subcell B to subcell C. Layer 213c is preferably composed of n++GaAs, and layer 213d is preferably composed of p++A1GaAs.

On top of the tunnel diode layers 213c/213d a BSF layer 214 is deposited, preferably p+ type A1GaAs. More generally, the BSF layer 214 used in the subcell C operates to reduce the interface recombination loss. It should be apparent to one skilled in the art, that additional layer(s) may be added or deleted in the cell structure without departing from the scope of the present invention.

On top of the BSF layer 214, the layers of subcell C are deposited: the p type base layer 215 and the n+ type emitter layer 216. These layers are preferably composed of InGaAs and InGaAs or InGaP, respectively, although any other suitable materials consistent with lattice constant and bandgap requirements may be used as well. Thus, subcell C may be composed of a GaAs, GaInP, GaInAs, GaAsSb, or GaInAsN emitter region and a GaAs, GaInAs, GaAsSb, or GaInAsN base region. The band gap of subcell C may be approximately 1.25 to 1.4 eV. The doping profile of layers 215 and 216 according to the present invention will be discussed in conjunction with FIG. 9.

On top of the subcell C is deposited a window layer 217 composed of InA1P which performs the same function as the window layer 212. The p++/n++tunnel diode layers 218a and 218b respectively are deposited over the window layer 217, similar to the layers 213c and 213d, forming an ohmic circuit element to connect subcell C to subcell D. The layer 218a is preferably composed of n++InGaP, and layer 218b is preferably composed of p++A1GaAs.

A BSF layer 219, preferably composed of p+ type A1GaAs, is then deposited over the tunnel diode layer 218b. This BSF layer operates to reduce the recombination loss in subcell “D”. It should be apparent to one skilled in the art that additional layers may be added or deleted in the cell structure without departing from the scope of the present invention.

On top of the BSF layer 219 the layers of subcell D are deposited: the p type base layer 220 and the n+ type emitter layer 221. These layers are preferably composed of p type InGaP and n+ type InGaP, respectively, although any other suitable materials consistent with lattice constant and bandgap requirements may be used as well. The band gap of subcell D may be approximately 1.85 eV. The doping profile of layers 220 and 221 according to the present invention will be discussed in conjunction with FIG. 9. A window layer 222, preferably composed of n+ type InA1P is then deposited on top of the subcell D, the window layer performing the same function as the window layers 207, 212, and 217.

FIG. 2C depicts the multijunction solar cell in another embodiment according to the present invention after the sequential formation of the five subcells A, B, C, D and E on a germanium growth substrate. More particularly, there is shown a substrate 201, which is preferably germanium (Ge) or other suitable material.

The composition of layers 201 through 212 in the embodiment of FIG. 2C are similar to those described in the embodiment of FIG. 2A, but with different elemental compositions or dopant concentrations necessary to achieve to different band gaps, and therefore the description of such layers need not be repeated here. In particular, in the embodiment of FIG. 2C, the band gap of subcell A may be approximately 0.73 eV, the band gap of subcell B may be approximately 0.95 eV, and the band gap of subcell C may be approximately 1.24 eV. We therefore continue the description of the embodiment of FIG. 2C with the layers on top of the window layer 212.

On top of the window layer 212 is deposited a sequence of heavily doped p-type and n-type layers 213e and 213f that form a tunnel diode, i.e. an ohmic circuit element that connects subcell A to subcell B. Layer 213e is preferably composed of n++GeSiSn, and layer 213f is preferably composed of p++GeSiSn.

On top of the tunnel diode layers 213e/213f a BSF layer 214a is deposited, preferably p+ type GeSiSn. More generally, the BSF layer 214a used in the subcell C operates to reduce the interface recombination loss. It should be apparent to one skilled in the art, that additional layer(s) may be added or deleted in the cell structure without departing from the scope of the present invention.

On top of the BSF layer 214a, the layers of subcell C are deposited: the p type base layer 215a and the n+ type emitter layer 216a. These layers are preferably composed of GeSiSn, although any other suitable materials consistent with lattice constant and bandgap requirements may be used as well. Thus, subcell C may be composed of a GaAs, GaInP, GaInAs, GaAsSb, or GaInAsN emitter region and a GaAs, GaInAs, GaAsSb, or GaInAsN base region. The band gap of subcell C may be approximately 1.24 eV. The doping profile of layers 215a and 216a according to the present invention will be discussed in conjunction with FIG. 9.

On top of the subcell C is deposited a window layer 217a composed of InA1P which performs the same function as the window layer 207 and 212. The p++/n++tunnel diode layers 218e and 218d respectively are deposited over the window layer 217a, similar to the layers 208a and 208b and 213e and 213f, forming an ohmic circuit element to connect subcell C to subcell D. The layer 218c is preferably composed of n++InGaAsP, and layer 218d is preferably composed of p++A1GaAs.

A BSF layer 219a, preferably composed of p+ type A1GaAs, is then deposited over the tunnel diode layer 218d. This BSF layer operates to reduce the recombination loss in subcell “D”. It should be apparent to one skilled in the art that additional layers may be added or deleted in the cell structure without departing from the scope of the present invention.

On top of the BSF layer 219a the layers of subcell D are deposited: the p type base layer 220a and the n+ type emitter layer 221a. These layers are preferably composed of p type InGaAsP or A1GaInAs and n+ type InGaAsP or AlGaInAs, respectively, although any other suitable materials consistent with lattice constant and bandgap requirements may be used as well. The band gap of subcell D may be approximately 1.6 eV. The doping profile of layers 220a and 221a according to the present invention will be discussed in conjunction with FIG. 9.

A window layer 222a, preferably composed of n+ type InA1P, InGaAsP, or A1GaInAs, is then deposited on top of the subcell D, the window layer performing the same function as the window layers 207, 212, and 217a.

The p++/n++tunnel diode layers 223a and 223b respectively are deposited over the window layer 222a, similar to the layers 218c and 218d, forming an ohmic circuit element to connect subcell D to subcell E. The layer 223a is preferably composed of n++InGaAsP, and layer 223b is preferably composed of p++A1GaAs.

A BSF layer 224, preferably composed of p+ type A1GaAs or InGaA1P, is then deposited over the tunnel diode layer 223b. This BSF layer operates to reduce the recombination loss in subcell “E”. It should be apparent to one skilled in the art that additional layers may be added or deleted in the cell structure without departing from the scope of the present invention.

On top of the BSF layer 224 the layers of subcell E are deposited: the p type base layer 225 and the n+ type emitter layer 226. These layers are preferably composed of p type A1GaInP and n+ type A1GaInP, respectively, although any other suitable materials consistent with lattice constant and bandgap requirements may be used as well. The band gap of subcell E may be approximately 2.0 eV. The doping profile of layers 224 and 225 according to the present invention will be discussed in conjunction with FIG. 9.

A window layer 227, preferably composed of n+ type InA1P is then deposited on top of the subcell E, the window layer 227 performing the same function as the window layers 207, 212, 217a and 222a.

FIG. 3 is a highly simplified cross-section view of the solar cell of any of FIG. 2A, 2B, or 2C which shows the next process step in which a high band gap contact layer 250, preferably composed of n+ type InGaAs, is deposited on the window layer 249, which represents the window layer 217, 222, or 227, of FIGS. 2A, 2B, and 2C respectively, as the case may be. Subsequent figures will utilize the highly simplified cross-section view of this FIG. 3, it being understood that the description of the subsequent fabrication of the solar cell may be referring to any of the depicted embodiments of FIG. 2A, 2B, or 2C, or any of additional or similar embodiments described thereinabove.

In addition to the contact layer 250, it should be apparent to one skilled in the art, that additional layer(s) may be added or deleted in the cell structure on top of the subcell structure without departing from the scope of the present invention.

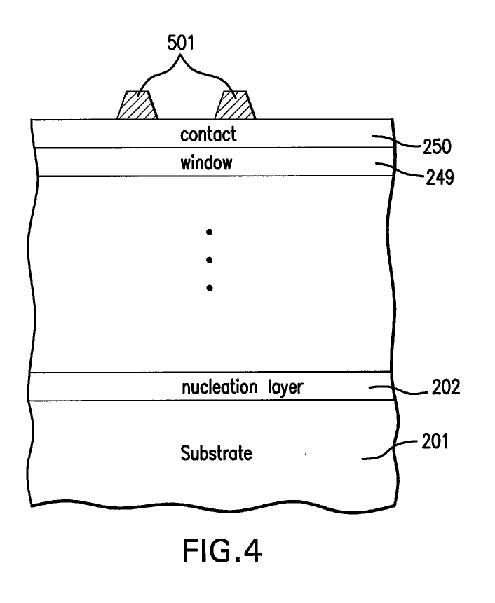

FIG. 4 is a cross-sectional view of the solar cell of FIG. 3 after the next sequence of process steps in which a photoresist layer (not shown) is placed over the semiconductor contact layer 318. The photoresist layer is lithographically patterned with a mask to form the locations of the grid lines 501, portions of the photoresist layer where the grid lines are to be formed are removed, and a metal contact layer 319 is then deposited by evaporation or similar processes over both the photoresist layer and into the openings in the photoresist layer where the grid lines are to be formed. The photoresist layer portion covering the contact layer 318 is then lifted off to leave the finished metal grid lines 501, as depicted in the Figures. The grid lines 501 are preferably composed of the sequence of layers Pd/Ge/Ti/Pd/Au, although other suitable sequences and materials may be used as well.

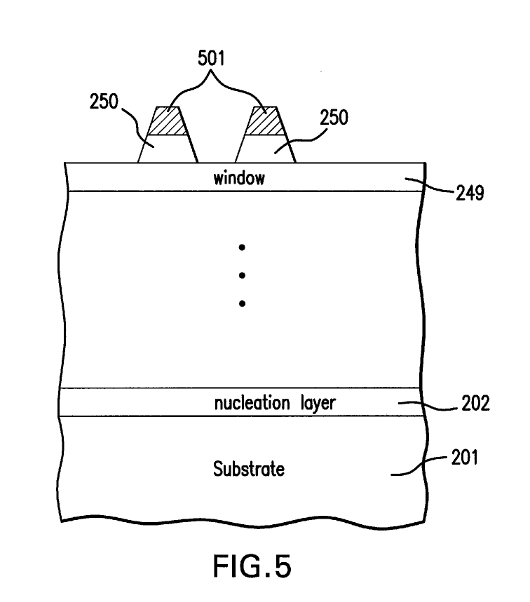

FIG. 5 is a cross-sectional view of the solar cell of FIG. 4 after the next process step in which the grid lines are used as a mask to etch down the surface to the window layer 249 using a citric acid/peroxide etching mixture.

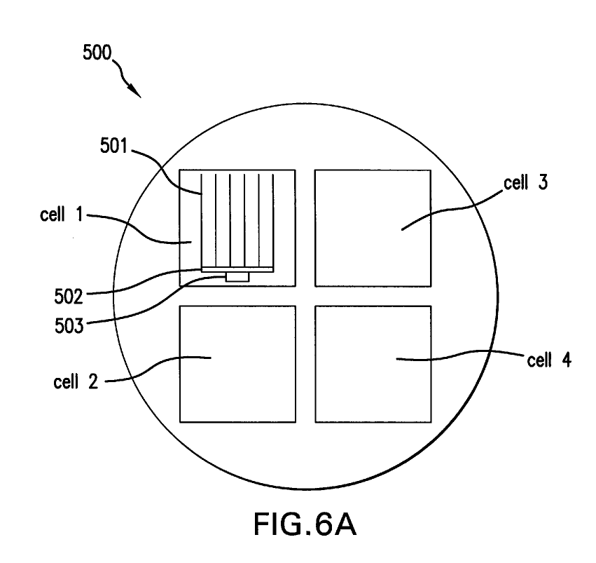

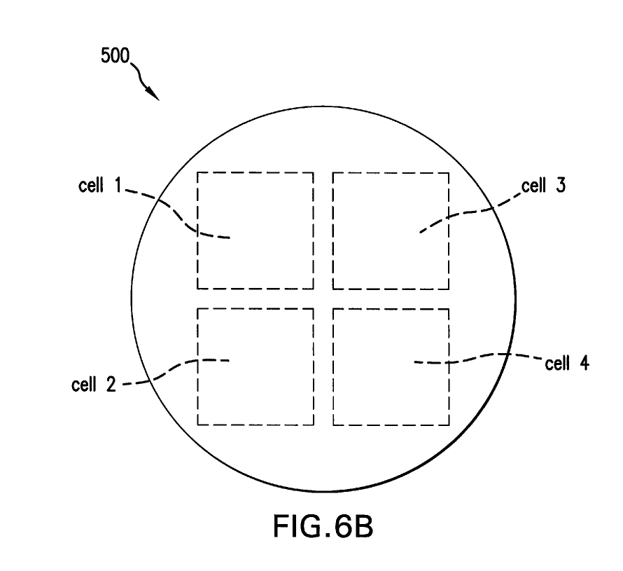

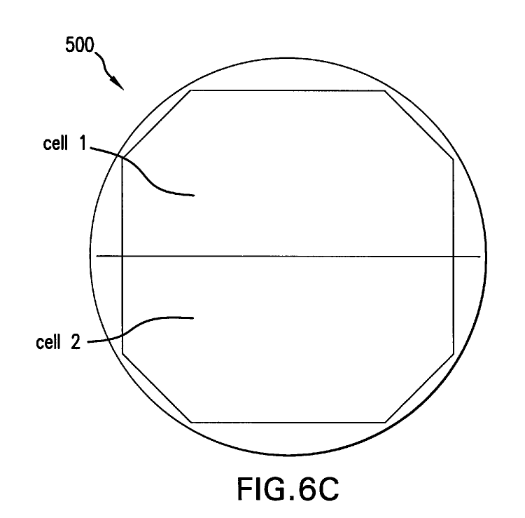

FIG. 6A is a top plan view of a 100 mm (or 4 inch) wafer in which four solar cells are implemented. The depiction of four cells is for illustration for purposes only, and the present invention is not limited to any specific number of cells per wafer.

In each cell there are grid lines 501 (more particularly shown in cross-section in FIG. 5), an interconnecting bus line 502, and a contact pad 503. The geometry and number of grid and bus lines and contact pads are illustrative, and the present invention is not limited to the illustrated embodiment.

FIG. 6B is a bottom plan view of the wafer of FIG. 6A, showing in outline the position of the four solar cells.

FIG. 6C is a top plan view of a 100 mm (or 4 inch) wafer in which two solar cells are implemented. Although various geometric polygonal shapes may be utilized to define the boundary of the solar cells within the wafer, in the illustrated geometric configuration, each solar cell has an area of 26.3 cm².

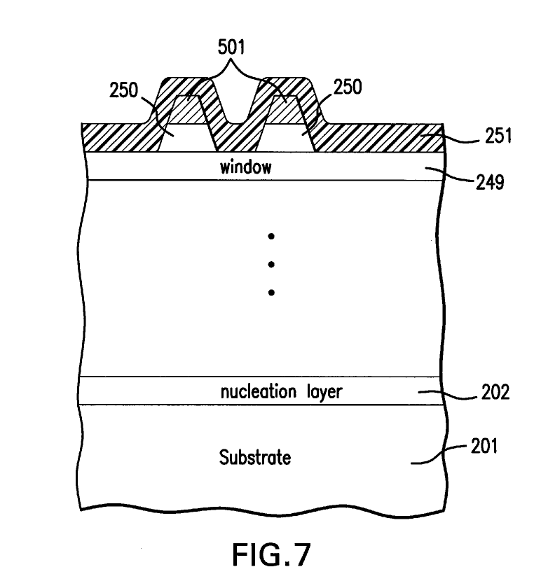

FIG. 7 is a cross-sectional view of the solar cell of FIG. 5 after the next process step in which an antireflective (ARC) dielectric coating layer is applied over the entire surface of the top side of the wafer with the grid lines 501.

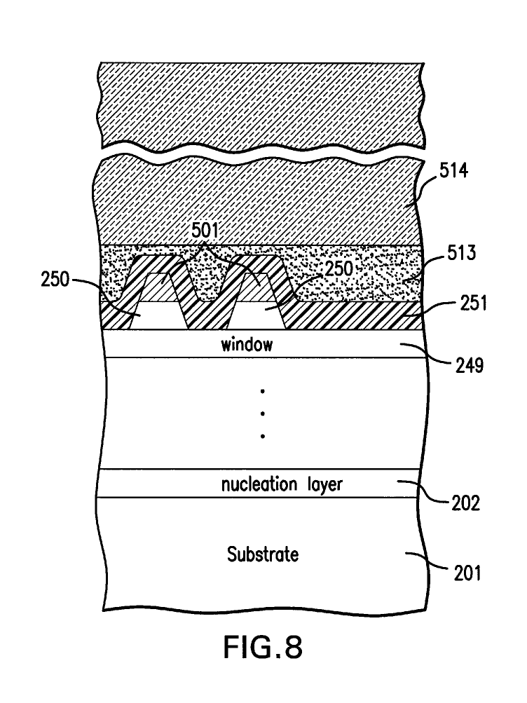

FIG. 8 is a cross-sectional view of the solar cell of FIG. 7 after the next process step in a second embodiment of the present invention in which a cover glass 514 is secured to the top of the cell by an adhesive 513. The cover glass 514 is typically about 4 mils thick and preferably covers the entire channel 510, extends over a portion of the mesa 516, but does not extend to channel 511. Although the use of a cover glass is desirable for many environmental conditions and applications, it is not necessary for all implementations, and additional layers or structures may also be utilized for providing additional support or environmental protection to the solar cell.

FIG. 9 is a graph of a doping profile in the emitter and base layers in one or more subcells of the multijunction solar cell of the present invention. The various doping profiles within the scope of the present invention, and the advantages of such doping profiles are more particularly described in copending U.S. patent application Ser. No. 11/956,069 filed Dec. 13, 2007, herein incorporated by reference. The doping profiles depicted herein are merely illustrative, and other more complex profiles may be utilized as would be apparent to those skilled in the art without departing from the scope of the present invention.

It will be understood that each of the elements described above, or two or more together, also may find a useful application in other types of constructions differing from the types of constructions described above.

In addition, although the illustrated embodiment is configured with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, the present invention may utilize an arrangement of one or more, or all, homojunction cells or subcells, i.e., a cell or subcell in which the p-n junction is formed between a p-type semiconductor and an n-type semiconductor both of which have the same chemical composition and the same band gap, differing only in the dopant species and types. A subcell with p-type and n-type InGaP is one example of a homojunction subcell. Alternatively, as more particularly described in U.S. Pat. No. 7,071,407, the present invention may utilize one or more, or all, heterojunction cells or subcells, i.e., a cell or subcell in which the p-n junction is formed between a p-type semiconductor and an n-type semiconductor having different chemical compositions of the semiconductor material in the n-type regions, and/or different band gap energies in the p-type regions, in addition to utilizing different dopant species and type in the p-type and n-type regions that form the p-n junction. In some cells, a thin so-called “intrinsic layer” may be placed between the emitter layer and base layer, with the same or different composition from either the emitter or the base layer. The intrinsic layer may function to suppress minority-carrier recombination in the space-charge region. Similarly, either the base layer or the emitter layer may also be intrinsic or not-intentionally-doped (“NID”) over part or all of its thickness. Some such configurations are more particularly described in copending U.S. patent application Ser. No. 12/253,051, filed Oct. 16, 2008.

The composition of the window or BSF layers may utilize other semiconductor compounds, subject to lattice constant and band gap requirements, and may include A1InP, AlAs, A1P, A1GaInP, A1GaAsP, A1GaInAs, A1GaInPAs, GaInP, GaInAs, GaInPAs, A1GaAs, A1InAs, A1InPAs, GaAsSb, A1AsSb, GaA1AsSb, A1InSb, GaInSb, A1GaInSb, AIN, GaN, InN, GaInN, A1GaInN, GaInNAs, A1GaInNAs, ZnSSe, CdSSe, and similar materials, and still fall within the spirit of the present invention.

While the invention has been illustrated and described as embodied in a multijunction solar cell, it is not intended to be limited to the details shown, since various modifications and structural changes may be made without departing in any way from the spirit of the present invention.

Thus, while the description of this invention has focused primarily on solar cells or photovoltaic devices, persons skilled in the art know that other optoelectronic devices, such as thermophotovoltaic (TPV) cells, photodetectors and light-emitting diodes (LEDS) are very similar in structure, physics, and materials to photovoltaic devices with some minor variations in doping and the minority carrier lifetime. For example, photodetectors can be the same materials and structures as the photovoltaic devices described above, but perhaps more lightly-doped for sensitivity rather than power production. On the other hand LEDs can also be made with similar structures and materials, but perhaps more heavily-doped to shorten recombination time, thus radiative lifetime to produce light instead of power. Therefore, this invention also applies to photodetectors and LEDs with structures, compositions of matter, articles of manufacture, and improvements as described above for photovoltaic cells.

The foregoing described embodiments depict different components contained within, or connected with, different other components. It is to be understood that such depicted arrangements or architectures are merely exemplary, and that in fact many other arrangements or architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of specific structures, architectures or intermedial components. Likewise, any two components so associated can also be viewed as being “operably connected” or “operably coupled” to each other to achieve the desired functionality.

While particular embodiments of the present invention have been shown and described, it will be understood by those skilled in the art that, based upon the teachings herein, changes and modifications may be made without departing from this invention and its broader aspects and, therefore, the appended claims are to encompass within their scope all such changes and modifications as are within the true spirit and scope of this invention. Furthermore, it is to be understood that the invention is solely defined by the appended claims. It will be understood by those within the art that, in general, terms used herein, and especially in the appended claims (e.g., in the bodies of the appended claims) are generally intended as “open” terms (e.g., the term “including” should be interpreted as “including but not limited to,” the term “having” should be interpreted as “having at least,” the term “includes” should be interpreted as “includes but is not limited to,” “comprise” and variations thereof, such as, “comprises” and “comprising” are to be construed in an open, inclusive sense, that is as “including, but not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A method of manufacturing a solar cell comprising:
providing a germanium semiconductor growth substrate;
depositing on said semiconductor growth substrate a sequence of layers of semiconductor material forming a solar cell, including a subcell composed of a group IV/III-V hybrid alloy.

2. A method as defined in claim 1, wherein the group IV/III-V hybrid alloy is GeSiSn.

3. A method as defined in claim 2, wherein the GeSiSn subcell has a band gap in the range of 0.8 eV to 1.2 eV.

4. A method as defined in claim 3, further comprising a subcell composed of germanium deposited between said GeSiSn subcell and the germanium substrate.

5. A method as defined in claim 1, wherein the sequence of layers includes a first GeSiSn subcell having a band gap in the range of 0.91 eV to 0.95 eV, and a second GeSiSn subcell having a band gap in the range of 1.13 eV to 1.24 eV.

6. A method as defined in claim 1, wherein said step of depositing a sequence of layers of semiconductor material includes forming a first solar subcell on said substrate composed of GeSiSn and having a first band gap; forming a second solar subcell over said first subcell composed of InGaAs having a second band gap greater than said first band gap; and forming a third solar subcell composed of GaInP over said second solar subcell having a third band gap greater than said second band gap.

7. A method as defined in claim 1, wherein said step of depositing a sequence of layers of semiconductor material includes forming a first solar subcell on said substrate composed of Ge and having a first band gap; forming a second solar subcell over said first subcell composed of GeSiSn having a second band gap greater than said first band gap; and forming a third solar subcell composed of InGaAs over said second solar subcell having a third band gap greater than said second band gap; and forming a fourth solar subcell composed of GaInP having a fourth band gap greater than said third band gap and lattice matched to said third solar subcell.

8. A method as defined in claim 1, wherein said step of depositing a sequence of layers of semiconductor material includes forming a first solar subcell on said substrate composed of Ge and having a first band gap; forming a second solar subcell over said first subcell composed of GeSiSn having a second band gap greater than said first band gap; and forming a third solar subcell composed of GeSiSn over said second solar subcell having a third band gap greater than said second band gap; and forming a fourth solar subcell composed of InGaAs having a fourth band gap greater than said third band gap and lattice matched to said third solar subcell; forming a fifth solar subcell composed of GaInP having a fifth band gap greater than said fourth band gap and lattice matched to said fourth solar subcell.

9. A method as defined in claim 1, wherein some of said layers are deposited with metal organic chemical vapor deposition processes at a temperature around 700° C.

10. A method as defined in claim 1, wherein the coefficient of thermal expansion between the growth substrate and the layers of semiconductor material are suitably matched to avoid cracking.

11. A method as defined in claim 7, further comprising forming a tunnel diode composed of GeSiSn between the first subcell composed of Ge and the second subcell composed of GeSiSn.

12. A method as defined in claim 1, further comprising depositing a BSF layer composed of GeSiSn over said growth substrate.

13. A method as defined in claim 1, wherein the group IV/III-V hybrid alloy is deposited by chemical vapor deposition at a temperature around 300° C.

14. A method as defined in claim 1, further comprising depositing a Ge buffer layer over said germanium growth substrate.

15. A method as defined in claim 4, further comprising forming a GeSiSin BSF layer and a GeSiSn window layer adjacent to said germanium subcell.

16. A method as defined in claim 4, wherein the germanium subcell has a band gap of approximately 0.73 eV.

17. A method as defined in claim 1, wherein a junction is formed in the group IV/III-V hybrid alloy to form a photovoltaic subcell by the diffusion of As and/or P into the hybrid alloy layer.

18. A method as defined in claim 1, further comprising forming window and BSF layers composed of the group IV/III-V hybrid alloy adjacent to the subcell composed of the group IV/III-V hybrid alloy.

19. A method of manufacturing a solar cell comprising:
providing a semiconductor growth substrate; and
depositing on said semiconductor growth substrate a sequence of layers of semiconductor material forming a solar cell, including at least one layer composed of GeSiSn and one layer grown over the GeSiSn layer composed of Ge.

20. A multijunction solar cell comprising:
a first solar subcell composed of GeSiSn and having a first band gap;
a second solar subcell composed of GaAs, InGaAsP, or InGaP and disposed over the first solar subcell having a second band gap greater than the first band gap and lattice matched to said first solar subcell; and
a third solar subcell composed of GaInP and disposed over the second solar subcell having a third band gap greater than the second band gap and lattice matched with respect to the second subcell.
